(19) United States
(12) Patent Application Publication
(10) Pub. No.: US 2003/0113510 A1
(43) Pub. Date: Jun. 19, 2003

(54) Multi-layers with vias in filled holes

(76) Inventors: Mark S. Lopac, Cokato, MN (US); David R. Backen, Eden Prairie, MN (US); Kevin C. Dane, Monticello, MN (US); Steve H. Schultz, Minneapolis, MN (US)

Correspondence Address: ROBERT D. FISH; RUTAN & TUCKER, LLP, P.O. BOX 1950, 611 ANTON BLVD., 14TH FLOOR, COSTA MESA, CA, 92628-1950, US

(21) Appl. No.: 10/033,277

(22) Filed: Dec. 17, 2001

(51) Int. Cl. B32B 3/10; H05K 1/00; H05K 1/16; H01K 3/10

(52) U.S. Cl. 428/138; 174/250; 174/260; 29/852

(57) ABSTRACT

Multi-layers having at least one plated and filled via or through hole in which a portion of the material filling the via or through hole is removed to allow the spaced previously occupied by the removed material to be used for some other purpose. In some multi-layers, the removed material will be replaced by a second plated via or through hole thus providing additional interconnect options or to functioning as a part of a larger component.

### FIELD OF THE INVENTION

The field of the invention is multi-layer devices having plated through holes and methods relating to their formation.

### BACKGROUND OF THE INVENTION

It is not uncommon to have a multi-layer substrate (“multi-layer”) comprising a core sandwiched between two circuitized copper layers. Such multi-layers have a variety of uses including, but not necessary limited to, being part of a printed wiring board, integrated circuit, or integrated circuit interconnect. In many instances such multi-layers will also include one or more plated vias or through holes wherein the via or through holes has plated sidewalls and a filled center.

Unfortunately, the amount of available space on such a multi-layer tends to be a limiting factor when designing a device that includes such a multi-layer. As such, there is a continuing need for new methods and devices that facilitate more efficient use of available space on multi-layers.

It is known to form a via or through hole in which the conductive portion of the via or through hole is insulated from the sidewalls of the hole through which it passes. Such insulated vias are useful when the via must pass through one or more conductive layers to which the via is not to be electrically coupled. Routing a via through a heat sink layer is one such application. However, insulating the conductive portion of the via from the sidewalls may actually require the use of more space on a multi-layer as the hole through which the conductive portion passes must be large enough to accommodate both the conductive portion and the surrounding insulation.

### SUMMARY OF THE INVENTION

The present invention is directed to multi-layers, and methods for forming multi-layers, that have at least one plated and filled via or through hole in which a portion of the material filling the via or through hole is removed to allow the spaced previously occupied by the removed material to be used for some other purpose. In preferred embodiments, the removed material will be replaced by a second plated via or through hole.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWINGS

FIG. 1 is a cutaway side view of a multi-layer comprising a plated through hole.

FIG. 2 is a cutaway side view of the multi-layer of FIG. 1 further comprising additional dielectric and conductive layers.

FIG. 3 is a cutaway side view of the multi-layer of FIG. 2 further a second hole drilled through the center of the original plated through hole.

FIG. 4 is a cutaway side view of the multi-layer of FIG. 3 wherein the second hole has plated side walls and forms a second plated through hole passing through the first plated through hole originally found in FIG. 1.

### DETAILED DESCRIPTION

It is contemplated that more efficient use of space on a multi-layer may be accomplished by utilizing at least portions of the filled centers of plated and filled through holes for a purpose other than holding fill material. Such a purpose may be to function as a second plated through hole as shown in FIG. 4. In FIG. 4, a multi-layer substrate comprises a plated and filled through hole 20, and a plated through hole 30 that passes through the filled portion of through hole 20.

Formation of the multi-layer of FIG. 4 may be accomplished by (a) providing a multi-layer substrate comprising a plated and filled through hole; (b) adding additional layers to the multi-layer; (c) drilling a second via or through hole through the additional layers and at least partially into the filled portion of the plated and filled through hole; and (d) plating the sidewalls of the second via or through hole.

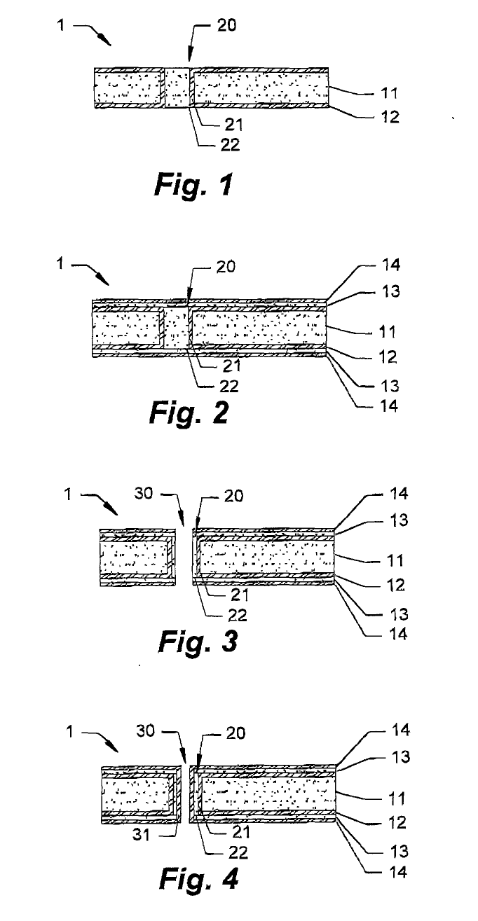

The step of providing a multi-layer substrate comprising a plated and filled through hole is illustrated by FIG. 1. In FIG. 1, a multi-layer 1 comprises a dielectric core 11, conductive layers 12, and through hole 20. Through hole 20 comprises conductive sidewalls 21 and filled center 22. For some designs, through hole 20 maybe larger than normal to provide for a larger filled center to facilitate formation of one or more additional components in the filled center. Multi-layer 1 may comprise any number of features not shown in FIG. 1, and may be comprised of a larger variety of materials. However, it is contemplated that a typical multilayer will comprise at least one C-stage core 11 and at least one circuitized conductive layer 12. Although the actual number of conductive layers 12 may vary between embodiments, it is contemplated that through hole 20 will electrically interconnect at least two circuitized conductive layers 12.

The step of adding additional layers to the multi-layer of FIG. 1 is illustrated by FIG. 2. In FIG. 2, the multi-layer of FIG. 1 further comprises additional dielectric layers 13 and conductive layers 14. Any means for adding additional layers may be used. As an example, the additional layers may be formed using known lamination or build-up techniques. It should be noted that at least a portion of two added conductive layers 14 overlap the filled center portion of through hole 20. Although this need not be the case in all embodiments, the overlap facilitates interconnection of layers 14 with the plated through hole to be formed within the center of through hole 20.

The step of drilling a second via or through hole through the additional layers and at least partially into the filled portion of the plated and filled through hole is illustrated by FIG. 3. In FIG. 3, the multi-layer of FIGS. 1 and 2 further comprises through hole 30 passing through the filled portion of through hole 20. Although mechanical drilling and laser drilling are the two most likely methods to be used to form through hole 30, any method of formation may be used so long as it is sufficient to remove the required amounts of fill material 22, preferably without damaging the conductive sidewalls 21, conductive layers 14 and 12, or any other portion of multi-layer 1.

The step of plating the sidewalls of the second via or through hole is illustrated by FIG. 4. In FIG. 4, as previously described, through hole 30 is plated so the multi-layer of FIG. 4 comprises a plated and filled through hole 20, and a plated through hole 30 that passes through the filled portion of through hole 20. The plating for through hole 30 may be accomplished by any reasonable method.

Although the figures illustrate the formation of a plated through hole within plated and filled through hole 20, it is contemplated that other components may be formed at least partially within the filled center portion of through hole 20. Such components may include, but are not necessarily limited to a bypass capacitor and an inductor.

For some applications, it may be necessary to include some extra steps in the formation process wherein the extra steps include: (a) identifying a filled and plated via or through hole to be used to at least partially contain another component; (b) determining whether the filled portion of the filled and plated via or through hole is large enough to contain the component; (c) if it is not large enough, enlarging the plated and filled via or through hole so that the filled center is large enough to contain the component. Such enlargement may occur during initial formation of the via or through hole, or may be done at a subsequent time by removing and reforming the plated and filled via or through hole.

Thus, specific embodiments and applications of multi-layers having one or more plated and filled through holes containing one ore more additional vias, through holes, or other components have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. A multi-layer substrate comprising a first plated and filled via or through hole wherein at least one component is located at least partially within the filled portion of the plated and filled via or through hole.

2. The multi-layer substrate of claim 1 wherein the at least one component is a second plated via or through hole.

3. The multi-layer substrate of claim 2 wherein the multi-layer substrate comprises a first plated and filled through hole and a second plated through hole passing through the filled portion of the first plated and filled through hole.

4. The multi-layer substrate of claim 1 wherein the at least one component is a by-pass capacitor or an inductor.

5. The multi-layer substrate of claim 1 wherein multi-layer substrate is a multi-layer printed circuit board.

6. A method of forming a multi-layer substrate comprising:
providing a multi-layer substrate comprising a first plated through hole, the plated through hole comprising a filled center;
adding additional layers to the multi-layer substrate;
removing a portion of the additional layers and a portion of the filled center of the plated through hole;
forming a component that extends at least partially into the removed portion of the filled center of the plated through hole.

7. The method of claim 6 wherein the component that extends at least partially into the removed portion of the filled center of the plated through hole is a plated via or through hole.

8. The method of claim 7 wherein the added surfaces comprise a first conductive layer positioned on one side of the provided multi-layer substrate and a second conductive surface positioned on an opposite side of the multi-layer substrate, and the component formed is a through hole that electrically couples the first conductive layer to the second conductive layer.

9. The method of claim 8 wherein the component is formed by first drilling and then plating a through hole passing through the first plated through hole.
